(19) United States
(12) Patent Application Publication
(10) Pub. No.: US 2026/0206371 A1
(43) Pub. Date: Jul. 16, 2026

(54) METHOD FOR MANUFACTURING A PLURALITY OF ELECTRONIC SEMICONDUCTOR CHIPS, ELECTRONIC SEMICONDUCTOR CHIP AND DISPLAY

(71) Applicant: ams International AG, Jona (CH)

(72) Inventors: Rainer MINIXHOFER, Premstätten (AT); Jörg SIEGERT, Graz (AT); Bernhard STERING, Stainz (AT)

(21) Appl. No.: 19/132,769

(22) PCT Filed: Nov. 7, 2023
(86) PCT No.: PCT/EP2023/080960

§ 371 Date: May 23, 2025

(30) Foreign Application Priority Data
Nov. 28, 2022 (DE) 10 2022 131 371.9

(51) Int. Cl. H10H 20/84; H10H 20/01; H10H 20/857; H10H 29/24

(52) U.S. Cl. CPC H10H 20/84; H10H 20/021; H10H 20/034; H10H 20/857; H10H 29/24

(57) ABSTRACT

A method for manufacturing a plurality of electronic semiconductor chips includes providing an epitaxial semiconductor layer sequence with a plurality of electronic functional regions, the epitaxial semiconductor layer sequence being arranged on or over a substrate, generating a plurality of trenches in the epitaxial semiconductor layer sequence, such that a plurality of epitaxial semiconductor layer stacks are created, depositing absorption layers on or over side faces of the epitaxial semiconductor layer stacks in the trenches, the absorption layers being absorbent for electromagnetic radiation, depositing a further layer on or over first main surfaces of the epitaxial semiconductor layer stacks, the further layer covering the trenches, generating bridging elements connecting the epitaxial semiconductor layer stacks starting from the first main surfaces to a handling wafer, and removing the substrate at least partially. Further, a semiconductor chip and a display are provided.

A method for manufacturing a plurality of electronic semiconductor chips, a semiconductor chip and a display are provided.

It is an object of the present application to provide an improved method for manufacturing a plurality of electronic semiconductor chips, in particular for manufacturing electronic semiconductor with low dimensions. Further, an improved electronic semiconductor chip, particularly with a low edge length is to be provided. Finally, an improved display is to be provided, particularly comprising an electronic semiconductor chip having small dimensions.

These problems are solved by a method with the steps of claim 1, by an electronic semiconductor chip with the features of claim 10, by an electronic semiconductor chip with the features of claim 11, by a display having the features of claim 14 and by a display having the features of claim 15.

Improved developments and embodiments of the method for manufacturing a plurality of electronic semiconductor chips, of the electronic semiconductor chip and of the display are given in the respective dependent claims.

According to an embodiment of the method for manufacturing a plurality of electronic semiconductor chips, an epitaxial semiconductor layer sequence is provided. The epitaxial semiconductor layer sequence comprises a plurality of electronic functional regions. The epitaxial semiconductor layer sequence is arranged on or over a substrate. For example, the epitaxial semiconductor layer sequence comprises or consists of silicon. Layers of the epitaxial layer sequence are stacked in a growth direction above each other. Perpendicular to the growth direction, a lateral direction is arranged.

With the term “over” it is indicated that the elements thus related to each other do not necessarily have to be in direct physical contact with each other. Rather, further elements may be arranged in between.

Particularly, the present method takes place as a batch process on wafer level manufacturing a plurality of electronic semiconductor chips in parallel. Particularly, the epitaxial semiconductor layer sequence is provided as a part of a wafer with a diameter of several inches. A batch process on wafer level particularly has the advantage of reduced process time.

For example, the substrate is part of a silicon on insulator wafer (SOI wafer). In general, a SOI wafer comprises or consists of a functional layer separated to a handling layer by an oxide layer. If the substrate is part of a SOI wafer, the epitaxial semiconductor layer sequence is, for example, the functional layer, while the substrate is the handling layer.

Further, it is possible that the substrate is a highly doped silicon wafer. The highly doped silicon wafer can be n-doped or p-doped. Particularly, a doping concentration of the highly doped silicon wafer is at least 10¹⁶ cm⁻³ up to 10¹⁹.

According to an embodiment of the method, a plurality of trenches is generated in the epitaxial semiconductor layer sequence, such that a plurality of epitaxial semiconductor layer stacks is created. For example, the trenches penetrate the epitaxial semiconductor layer sequence completely such that the substrate is freely accessible. Particularly, each trench separates two directly adjacent epitaxial semiconductor layer stacks. A side face of the epitaxial semiconductor layer stack forms simultaneously a side face of a trench. For example, the trenches are created by etching, such as dry etching or wet etching. Preferably, each epitaxial semiconductor stack comprises at least one electronic functional region. A width of the trenches is, for example, between 0.5 microns and 2 microns, limits inclusive. For example, the trenches penetrate the epitaxial semiconductor layer sequence as far as the substrate. Particularly, the trenches penetrate the epitaxial semiconductor layer sequence completely. For example, the substrate forms bottom faces of the trenches.

The epitaxial layer stacks have first main surfaces facing away from the substrate and second main surfaces opposite to the first main surfaces. The first main surfaces and the second main surfaces are connected to each other by side faces, arranged along the growth direction.

According to a further embodiment of the method, absorption layers are deposited on or over the side faces of the epitaxial semiconductor layer stacks in the trenches. The absorption layers are particularly absorbent for electromagnetic radiation. Particularly, one absorption layer is arranged on each side face of each epitaxial semiconductor layer stack. Preferably, the absorption layers cover the side faces of the epitaxial semiconductor layer stacks completely. However, a thickness of the absorbent layers is preferably such that a gap remains in the lateral direction between two absorbent layers arranged in a common trench over the side faces of different epitaxial semiconductor layer stacks. In other words, the absorbent layers do not fill the trenches completely.

According to a further embodiment of the method, a further layer is deposited on or over the first main surfaces of the epitaxial semiconductor layer stacks. The further layer covers the trenches, particularly completely, seen in plan view on the further layer.

Particularly, the absorption layers comprise or consist of a metallic material, for example tungsten. Further, the absorption layers can comprise or consist of highly doped polycrystalline silicon. For example, the absorption layers have a thickness of at least 50 nanometers. Particularly, the absorption layers have a thickness of smaller than 50% of the trench width.

According to a further embodiment of the method, bridging elements are generated connecting the epitaxial semiconductor layer stacks starting from the first main surfaces to a handling wafer. The handling wafer can comprise or consist of a crystalline material, such as silicon. Further, it is possible that the handling wafer comprises or consists of a polymer material, such as a duroplast or a thermoplast. For example, the handling wafer comprises or consists of an epoxide resin. In particular, the handling wafer is configured for mechanically stabilizing the wafer compound comprising the epitaxial semiconductor layer stacks, if the substrate is removed.

According to a further embodiment of the method, the substrate is removed at least partially. Particularly, the substrate is removed completely. For example, the substrate is removed by etching such as dry etching or wet etching.

Also, a mechanical technology can be used for removal of the substrate, such as grinding or polishing. Particularly, chemical mechanical polishing can be used for removing the substrate.

If a SOI wafer is used, the oxide layer acts preferably as an etch stop layer for an etching process to remove the substrate. If the substrate is part of a SOI wafer, the handling layer can be removed completely, while the oxide layer remains in the wafer compound. Further, it is possible that also the oxide layer is removed.

If a highly doped silicon wafer is used as a substrate, etching for removal of the substrate is stopped, particularly by the difference in doping concentration between the substrate and the epitaxial semiconductor layer stacks. For example, an etch stop layer of the epitaxial semiconductor layer stacks directly adjacent to the substrate needs at least 10¹⁸ cm⁻³ doping concentrations.

According to a further embodiment of the method, the electronic functional regions comprise or consist of pn-junctions configured for detecting electromagnetic radiation of a first wavelength range during operation. For example, the first wavelength range is the wavelength range between and including 400 nanometer to 1100 nanometer. Particularly, the absorption layers absorb electromagnetic radiation of the first wavelength range. In this embodiment of the method, photodiode semiconductor chips as electronic semiconductor chips are manufactured. Particularly, each electronic functional region comprises one or more pn-junctions for detecting electromagnetic radiation of the first wavelength range during operation. In this embodiment of the method, the absorption layers particularly absorb ambient light in order to enhance sensitivity of the pn-junctions.

According to a further embodiment of the method, the electronic functional region comprises or consist of an integrated circuit, for example configured for controlling a light-emitting diode chip during operation.

According to a further embodiment of the method, the absorption layers are electrically conductive. For example, the absorption layers comprise or consist of a metal, such as tungsten. A metallic absorption layer, for example comprising or consisting of tungsten, might be deposited by atomic layer deposition (ALD).

If the absorption layers are electrically conductive, electrically insulating layers are particularly preferably arranged between the side faces of the epitaxial semiconductor layer stacks and the absorption layers. The electrically insulating layers between the epitaxial semiconductor layer stacks and the absorption layers prevent a short circuit of the electronic functional region during operation of the finished electronic semiconductor chip.

The electrically insulating layers comprise or consist of an oxide or a nitride, such as silicon oxide or silicon nitride, for example. The electrically insulating layer is, for example, deposited by liquid phase chemical vapour deposition (LPCVD). If electrically insulating layers are arranged between the epitaxial semiconductor layer stacks and the absorption layers on or over the side faces of the epitaxial semiconductor layer stacks, the thickness of the absorption layers and the electrically insulating layers together is, for example, at least 50 nanometer. Particularly, the trenches are not filled completely by the absorption layers and the electrically insulating layers. In other words, the thickness of the absorption layers and the electrically insulating layers together is smaller than half of the trench width.

According to a further embodiment of the method, the further layer is a passivation layer and/or a release layer. The further layer can consist only of the release layer. Alternatively, the further layer can be a layer sequence comprising or consisting of the passivation layer and the release layer. In that case, the passivation layer is deposited before the release layer. For example, the passivation layer is deposited on the insulating layer and the release layer is deposited on the passivation layer. The passivation layer is, for example, deposited by plasma enhanced chemical vapour deposition (PECVD) or sub-atmospheric chemical vapour deposition (SACVD). The release layer comprises or consists of amorphous silicon, for example. The passivation layer particularly comprises or consists of an electrically insulting material.

According to a further embodiment of the method, the step of generating the bridging elements comprises depositing the release layer over the first main surfaces of the epitaxial semiconductor layer stacks, the release layer covering the trenches, particularly completely, seen in plan view. Further, recesses are generated in the release layer, the recesses completely penetrating the release layer. Particularly, the recesses are arranged in the release layer starting from the side face of the epitaxial semiconductor layer stack.

According to a further embodiment of the method, a polymer layer is deposited on the release layer. Particularly, the material of the polymer layer fills the recess in the release layer, preferably completely. After deposition of the polymer layer, the release layer is removed such that the epitaxial semiconductor layer stacks are connected to the handling wafer by the bridging elements. The bridging elements are particularly formed from the material of the polymer layer in the recesses of the release layer. For example, the polymer layer comprises or consists of benzocyclobutene (BCB). For example, the polymer layer is deposited by a spin coating process.

According to a further embodiment of the method, an adhesion layer is deposited between the polymer layer and the release layer. The adhesion layer has enhanced adhesion to the polymer layer compared to the adhesion between the polymer layer and the release layer.

According to a further embodiment of the method, the handling wafer is deposited on or over the polymer layer before removal of the substrate.

According to a further embodiment of the method, an optical filter layer is deposited on or over the second main surfaces of the epitaxial semiconductor layer stacks. The optical filter layer covers the trenches, particular preferably completely. According to a further embodiment of the method, the optical filter layer is removed over the trenches, for example by etching, in order to expose the release layer in the trenches. The optical filter layer, for examples, filters a part of the electromagnetic radiation of the first wavelength range. For example, the optical filter layer is an interference filter layer.

According to an embodiment of the method, the electronic functional regions comprise pn-junctions configured for detecting electromagnetic radiation of the first wavelength range during operation. In other words, the electronic functional regions are photodiodes. Preferably, the optical filter layer is an interference filter layer filtering a part of the electromagnetic radiation of the first wavelength range.

With the present method a plurality of electronic semiconductor chips can be manufactured. Particularly, the method generates a plurality of discrete electronic semiconductor chips only connected to the handling wafer via the bridging elements. The polymeric bridging elements are particularly small. For example, the bridging elements have dimensions of a few microns, for example between and including 1 micron and 5 microns. Therefore, the electronic semiconductor chips can be removed easily from the handling wafer, for example by a polymer stamp. The polymer stamp, for example made of polydimethylsiloxane (PDMS), has adhesion forces to the electronic semiconductor chip that are larger than the mechanical connection force imparted by the bridging elements. In such a way the electronic semiconductor chips can be removed from the handling wafer and transferred to a further element such as an electrical connection carrier, for example a printed circuit board (PCB), by the polymer stamp. Particularly, the polymer stamp allows very accurate transfer of electronic semiconductor chips having small dimensions from the handling wafer to the further element. For example, a thickness of the electronic semiconductor chip does not exceed 20 microns, while an edge length of the electronic semiconductor chip does not exceed 100 microns.

With the present method, particularly the absorption layers can be easily deposited on or over the side faces of the epitaxial semiconductor layer stacks. This is particularly achieved by filling the trenches with the absorption layers. The absorption layers on the side faces of the epitaxial semiconductor layer stacks particularly preferably at least reduce light penetrating into the electronic functional region. This is particularly advantageous, if the electronic functional region comprises or consists of a pn-junction or an integrated circuit. The absorption layer preferably blocks electromagnetic radiation, such as light, penetrating into the pn-junction or the integrated circuit. Such the sensitivity of the photodiode comprising the pn-junction or the reliability of the electronic semiconductor chip comprising the integrated circuit as an electronic functional region is enhanced.

Also, with the present method, a high performance interference filter is easily integrated on or over the first main surfaces of the epitaxial semiconductor layer stacks.

With the present method an electronic semiconductor chip can be manufactured. Therefore, features and embodiments disclosed in connection with the method can be also be embodied by the electronic semiconductor chip and vice versa.

According to an embodiment, the electronic semiconductor chip comprises an epitaxial semiconductor layer stack with an electronic functional region comprising a pn-junction configured to detect electromagnetic radiation of a first wavelength range during operation. For example, the pn-junction is configured to detect electromagnetic radiation of the wavelength range between 400 nm and 1100 nm. Particularly, the epitaxial semiconductor layer stack comprises or consists of silicon.

According to a further embodiment of the electronic semiconductor chip, an absorption layer covers side faces of the epitaxial semiconductor layer stack. The absorption layer absorbs electromagnetic radiation of the first wavelength range. For example, the absorption layer absorbs all or only some wavelengths from the first wavelength range. Further, it is possible that the absorption layer absorbs only a percentage of the intensity of the electromagnetic radiation or all of the intensity of the electromagnetic radiation.

According to a further embodiment, the electronic semiconductor chip comprises at least two electrical mounting pads configured for electrically conductive and mechanically stable connection of the electronic semiconductor chip to a further element such as a connection carrier. The electrical mounting pads are arranged at a back side surface of the electronic semiconductor chip. The back side surface of the electronic semiconductor chip runs parallel to the first and second main surfaces of the epitaxial semiconductor layer stacks. For example, the electronic semiconductor chip is connected to the further connection carrier by soldering of the electrical mounting pads.

According to a further embodiment, the electronic semiconductor chip comprises a radiation entrance surface configured for transmitting the electromagnetic radiation to be detected to the functional electronic region such as the pn-junction. In particular, the radiation entrance surface is arranged at a front side surface of the electronic semiconductor chip opposite to the back side surface. The front side surface of the electronic semiconductor chip and the back side surface of the electronic semiconductor chip are connected to each other by the side surfaces of the the electronic semiconductor chip.

For example, the absorption layer forms the side surface of the electronic semiconductor chip at least partially. Particularly, the absorption layer is freely accessible at the side surface of the electronic semiconductor chip.

It is further possible that the electronic functional region comprises an integrated circuit. In particular, the integrated circuit is configured to control a light emitting diode chip.

According to a further embodiment, the electronic semiconductor chip comprises an electrical mounting surface configured for mounting the light emitting diode chip to be controlled, wherein the electrical mounting surface is arranged at the front side surface of the electronic semiconductor chip opposite to the back side surface. For example, the mounting surface comprises at least two electrical connections areas configured for electrically conductively and mechanically stable connection of the LED chip to be controlled.

According to a further embodiment, a thickness of the electronic semiconductor chip does not exceed 20 microns.

According to a further embodiment, an edge length of the electronic semiconductor chip does not exceed 100 microns.

Particularly, the light emitting diode chip to be controlled is a micro-LED.

As a broad definition, a micro-LED could be seen as any light emitting diode (LED)-generally not a laser-with a particularly small size.

As a rule-and this is a very important criterion in addition to size-a growth substrate is removed from micro-LEDs, so that typical heights of such micro-LEDs are in the range of 1.5 micrometer to 10 micrometer, for example. Also, the electronic semiconductor chip described herein can be free of a substrate, particularly of a growth substrate. The electronic semiconductor chip has a height in the range of 1.5 micrometer to 10 micrometer, for example.

In principle, a micro-LED does not necessarily have to have a rectangular radiation emission surface. Generally, for example, an LED could have a radiation emission surface in which, in plan view of the layers of the layer stack, any lateral extent of the radiation emission surface is less than or equal to 100 micrometer or less than or equal to 70 micrometer. Also, the electronic semiconductor chip described herein can have a base area with a lateral extend less than or equal to 100 micrometer or less than or equal to 70 micrometer. For example, the edge length of the electronic semiconductor chip is less than or equal to 100 micrometer or less than or equal to 70 micrometer.

For example, in the case of rectangular micro-LEDs, an edge length—especially in plan view of the layers of the layer stack—smaller than or equal to 70 micrometer or smaller than or equal to 50 micrometer is often cited as a criterion.

Mostly, such micro-LEDs are provided on wafers with—for the μLED non-destructively—detachable holding structures.

At present, micro-LEDs are mainly used in displays. The micro-LEDs form pixels or subpixels and emit light of a defined color. Small pixel size and a high density with close distances make micro-LEDs suitable, among others, for small monolithic displays for AR applications, especially data glasses. In addition, other applications are being developed, in particular regarding the use in data communication or pixelated lighting applications.

Different ways of spelling micro-LED, e.g. μLED, μ-LED, uLED, u-LED or micro light emitting diode can be found in the relevant literature.

The present electronic semiconductor chips are particularly configured to be introduced in a display. Embodiments and features described in connection with the electronic semiconductor chips are therefore also disclosed in connection with the display and vice versa.

According to an embodiment, the display comprises an electronic semiconductor chip. Particularly, the electronic semiconductor chip comprises a pn-junction configured for detecting parameters of electromagnetic radiation such as ambient light. For example, the electronic semiconductor chip is configured to measure intensity or spectral composition of the ambient light.

According to a further embodiment, the display comprises a light emitting diode chip emitting electromagnetic radiation of a second wavelength range during operation. For example, the light emitting diode chip is a micro-LED. Particularly preferably, the display comprises a plurality of light emitting diode chips, the light emitting diode chips forming pixels of the display. For example, the light emitting diode chips emit light of different colors, such as red light, green light and/or blue light. For example, one pixel of the display comprises at least one red light emitting chip, at least one green light emitting chip and at least one blue light emitting chip.

According to a further embodiment of the display, the electronic functional region of the epitaxial semiconductor layer stack of the electronic semiconductor chip comprises an integrated circuit configured to control the light emitting diode chip. In that case, the electronic semiconductor chip and the light-emitting diode chip are particularly preferably stacked above each other.

Particularly preferably, also the light emitting diode has very low dimensions such as a thickness not exceeding 20 microns and an edge length not exceeding 100 microns. If the electronic semiconductor chip and the light emitting diode chip are integrated together in a common display, they have preferably the same or similar dimensions. Preferably, the dimensions of the electronic semiconductor chip is not exceeding a pitch distance between consecutive light emitting diode chips.

The electronic semiconductor chip can be also configured to be used in augmented reality, virtual reality applications and/or in micro-projectors, particularly for controlling a light emitting diode chip or detecting electromagnetic radiation such as ambient light.

Further advantageous embodiments and developments of the method for manufacturing a plurality of electronic semiconductor chips, the electronic semiconductor chips and the displays result from the exemplary embodiments described below in connection with the Figures.

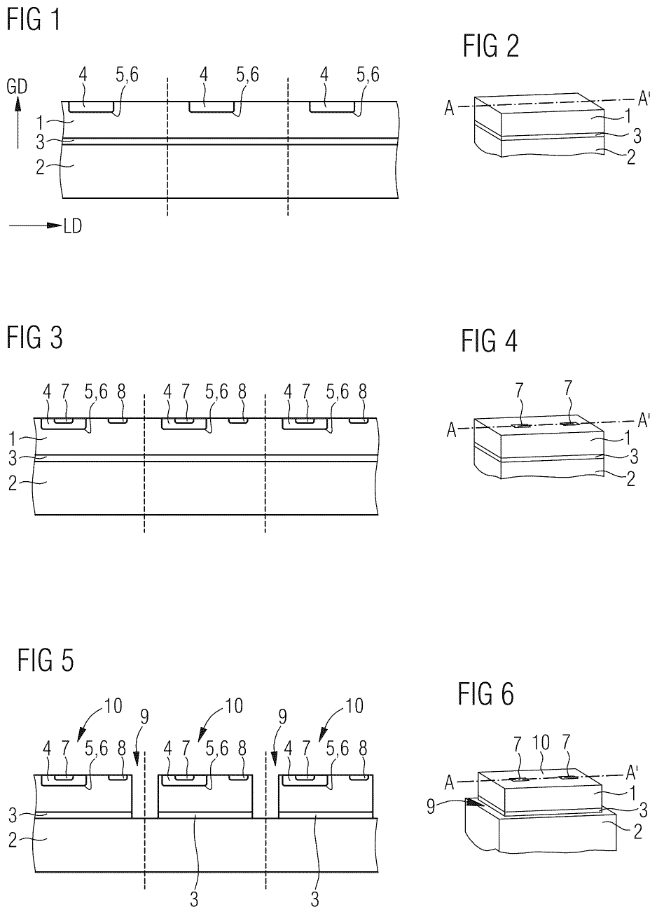

FIGS. 1 to 36 schematically show stages of a method for manufacturing a plurality of electronic semiconductor chips according to an exemplary embodiment.

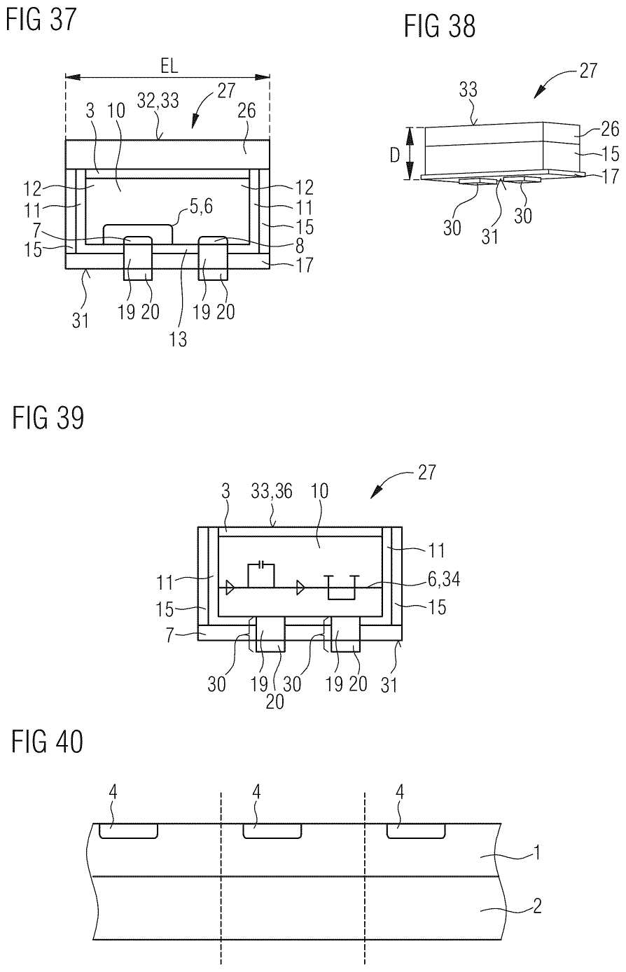

FIGS. 37 and 38 schematically show an electronic semiconductor chip according to an exemplary embodiment.

FIG. 39 shows a schematic sectional view of an electronic semiconductor chip according to a further exemplary embodiment.

FIG. 40 shows a stage of a method for manufacturing a plurality of electronic semiconductor chips according to a further exemplary embodiment.

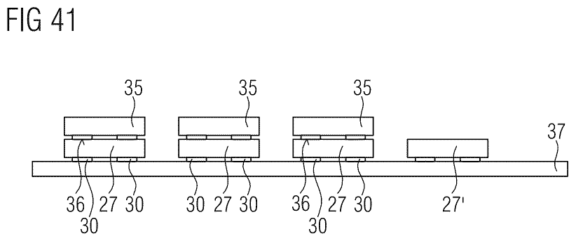

FIG. 41 shows a display according to an exemplary embodiment.

Equal or similar elements as well as elements of equal function are designated with the same reference signs in the Figures. The Figures and the proportions of the elements shown in the Figures are not regarded as being shown to scale. Rather, single elements, in particular layers, can be shown exaggerated in magnitude for the sake of better presentation and/or better understanding.

According to the method of the exemplary embodiment of FIGS. 1 to 36, an epitaxial semiconductor layer sequence 1 is provided in a first step (FIGS. 1 and 2). The epitaxial semiconductor layer sequence 1 is arranged on a substrate 2. Between the substrate 2 and the epitaxial semiconductor layer sequence 1 an oxide layer 3 is arranged. At present, the epitaxial semiconductor layer sequence 1 is based on silicon. Epitaxial layers of the epitaxial semiconductor layer sequence 1 are stacked above each other in a growth direction GD. Perpendicular to the growth direction GD runs a lateral direction LD.

At present, the epitaxial semiconductor layer sequence 1 and the substrate 2 as well as the oxide layer 3 are part of an SOI wafer, for example with a diameter of about 8 inch. The substrate 2 is the handling layer of the SOI wafer and the epitaxial semiconductor layer sequence 1 is the functional layer of the SOI wafer.

For example, the epitaxial semiconductor layer sequence 1 is p-doped. For example, the epitaxial semiconductor layer sequence 1 is p-doped with at least one of the following elements: B, In. The p-doping concentration is, for example, between and including 10¹² cm⁻³ und 10¹⁴cm⁻³.

In the p-doped epitaxial semiconductor layer sequencel, n-doped regions 4 are arranged, for example by ion implantation or ion diffusion in order to form pn-junctions 5 as electronic functional regions 6 within the epitaxial semiconductor layer sequence 1. The n-doped regions 4 comprise, for example, one of the following chemical elements as n-dopant: P, As, Sb. The n-doping concentration is, for example, between and including 10¹² cm⁻³ und 10¹⁴ cm⁻³.

FIG. 1 shows exemplarily a sectional view along the line A-A′ in FIG. 2 of an excerpt of the SOI wafer with three electronic functional regions 6. However, the SOI wafer as a whole comprises a much larger number of electronic functional regions 6, for example several hundred or several thousand.

FIG. 2 exemplarily shows a perspective view of only one electronic functional region 6 of the epitaxial semiconductor layer sequence 1 of FIG. 1. Also, the other method steps are shown in a sectional view along a line AA′ of an excerpt of the wafer with three electronic functional regions 6 and a perspective view of one functional region 6, respectively. The line AA′ indicating the section of the sectional view is shown in the respective corresponding perspective view.

In a further step, an n-doped contact regions 7 are inserted in the n-doped regions 4, for example by ion implantation or ion diffusion. Also, p-doped contact regions 8 are introduced in the p-doped epitaxial semiconductor layer sequence 1 (FIGS. 3 and 4).

Then, trenches 9 are generated in the epitaxial semiconductor layer sequence 1 in order to form a plurality of epitaxial semiconductor layer stacks 10 (FIGS. 5 and 6). At present, the trenches 9 penetrate the epitaxial semiconductor layer sequence 1 as far as the substrate 2. Particularly, the trenches 9 penetrate the epitaxial semiconductor layer sequence 1 and the oxide layer 3 completely.

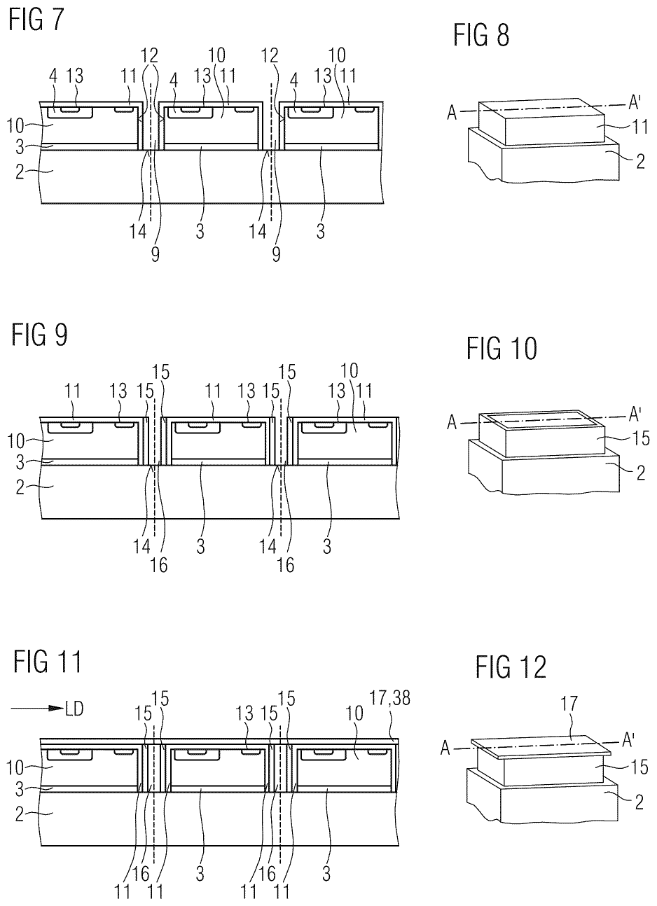

In a further step, electrically insulating layers 11 are deposited on side faces 12 of the epitaxial semiconductor layer stacks 10. The electrically insulating layers 11 cover the side faces 12 of the epitaxial semiconductor layer stacks 10 completely. For example, the material of the electrically insulating layers 11 is applied to the whole surface of the wafer compound in a first step, such that besides first main surfaces 13 and the side surfaces 12 of the epitaxial semiconductor layer stacks 10 also bottom surfaces 14 of the trenches 9 are covered. The material of the electrically insulating layers 11 is back etched such that the electrically insulating layers 11 cover only the side faces 12 of the epitaxial semiconductor layer stacks 10 and the first main surfaces 13 of the epitaxial semiconductor layer stacks 10, while the bottom surfaces 14 of the trenches 9 are free of the electrically insulating layers 11 (FIGS. 7 and 8).

Then, absorption layers 15 are applied over the side faces 12 of the epitaxial semiconductor layer stacks 10. The absorption layers 15 completely cover the side faces 12 of the epitaxial semiconductor layer stacks 10 as, for example, shown in FIGS. 9 and 10. For example, the absorption layers 15 are made of tungsten and are electrically conductive. The electrically insulating layers 11 isolates the absorption layers 15 from the epitaxial semiconductor layer stacks 10 in order to prevent short circuits.

In order to deposit the absorption layers 15 on or over the side faces 12 of the epitaxial semiconductor stacks 10, tungsten is deposited on the whole surface of the waver compound and particularly on or over the epitaxial semiconductor layer stacks 10 and on the bottom surfaces 14 of the trenches 9. Then, the tungsten is removed over the first main surfaces 13 of the epitaxial semiconductor layer stacks 10 and from the bottom surfaces 14 of the trenches 9. In such a way, only the side faces 12 of the epitaxial semiconductor layer stacks 10 are completely covered by the absorption layers 15.

The insulating layers 11 and the absorption layers 15 form layer sequences on the side faces 12 of the epitaxial semiconductor layer stacks 10. The layer sequences do not fill the trenches 9 completely in the lateral direction LD. Rather, there is still a gap 16 between two directly adjacent layer sequences deposited on directly neighbouring epitaxial semiconductor layer stacks 10. In other words, the epitaxial semiconductor layer stacks 10 are laterally separated from each other by the gap 16.

As shown in FIGS. 11 and 12, a further layer 38, particularly a passivation layer 17, is deposited covering the first main surfaces 13 of the epitaxial semiconductor layer stacks 10 as well as the trenches 9. In a plan view on the wafer compound formed by the method steps according to FIGS. 1 to 10, the passivation layer 17 forms a closed surface. Particularly, the gaps 16 between two directly adjacent epitaxial semiconductor layer stacks 10 are covered by the passivation layer 17 but not filled with the passivation layer 17. The passivation layer 17, for example, comprises or consists of an electrically insulating material such as an oxide or nitride. The passivation layer 17, for example, has a thickness between 50 nanometer and 800 nanometer.

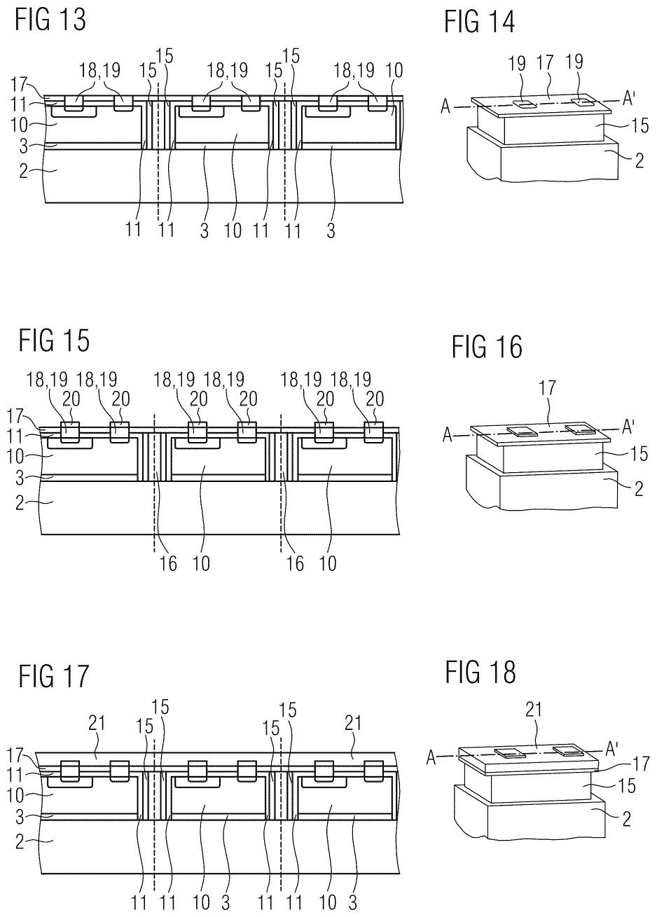

As shown, for example in FIGS. 13 and 14, openings 18 are etched within the passivation layer 17 and the insulating layers 11. The openings 18 completely penetrate the passivation layer 17 and the insulating layers 11. The openings 18 are filled with tungsten plugs 19 for electrical connection of the epitaxial semiconductor layer stacks 10. Then, metallic contact layers 20 are deposited on the tungsten plugs 19 (FIGS. 15 and 16).

Then, a release layer 21 is deposited over the first main surfaces 13 of the epitaxial semiconductor layer stacks 10. The wafer compound formed during the method steps described in connection with FIGS. 1 and 16 is completely covered by the release layer 21. The release layer 21 is, for example, made of amorphous silicon and has a thickness between and including 100 nanometer and 800 nanometer.

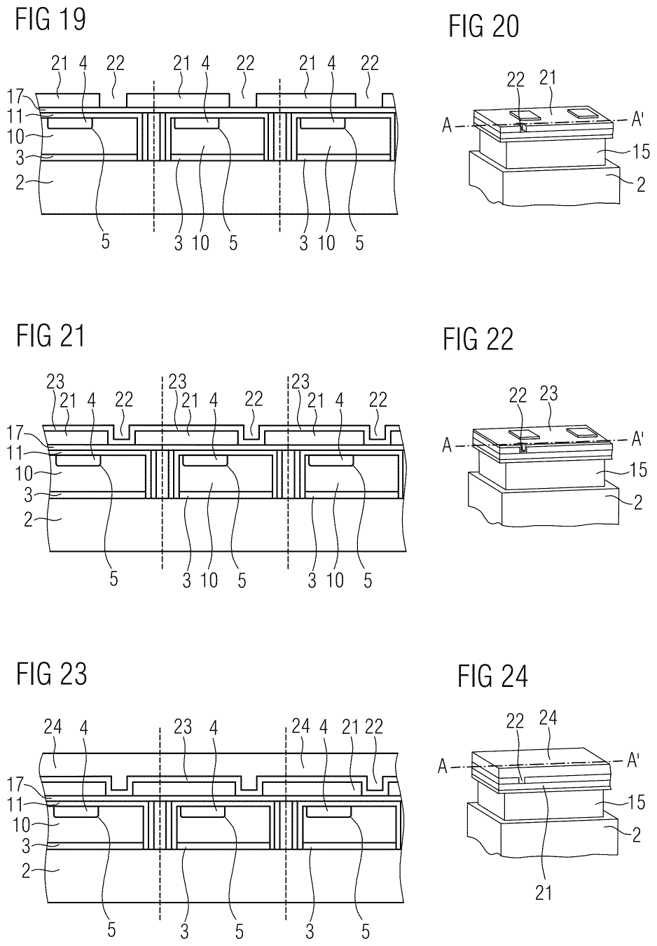

Then, recesses 22 are formed in the release layer 21. Particularly, the recesses 23 are formed starting from the side faces 12 of the epitaxial semiconductor layer stacks 10 (FIGS. 19 and 20). In order to illustrate the formation of the recesses 22 in more detail, line AA′ indicating the section of the sectional view in the perspective Figures are moved from the region of the formation of the electrical mounting pads to the recesses 22 in the perspective Figures of the method steps described in the following.

The recesses 22 completely penetrate the release layer 21 such that the underlying passivation layer 17 is directly accessible through the recesses 22.

As shown in FIGS. 21 and 22, an adhesion layer 23 is deposited on the release layer 21. The adhesion layer 23 has a better adhesion to a subsequent deposited polymer layer 24 then the release layer 17. Therefore, the adhesion layer enhances adhesion of the polymer layer 24 to be deposited. The adhesion layer 23 comprises for example of silicon dioxide or another dielectric material or consists of silicon dioxide or another dielectric material and has a thickness between 50 nanometer and 200 nanometer.

In a further step, the polymer layer 24, for example comprising or consisting of BCB, is applied to the whole wafer compound by a spin coating method (FIGS. 23 and 24). The polymer layer 24, for example, has a thickness between 5 microns and 100 microns.

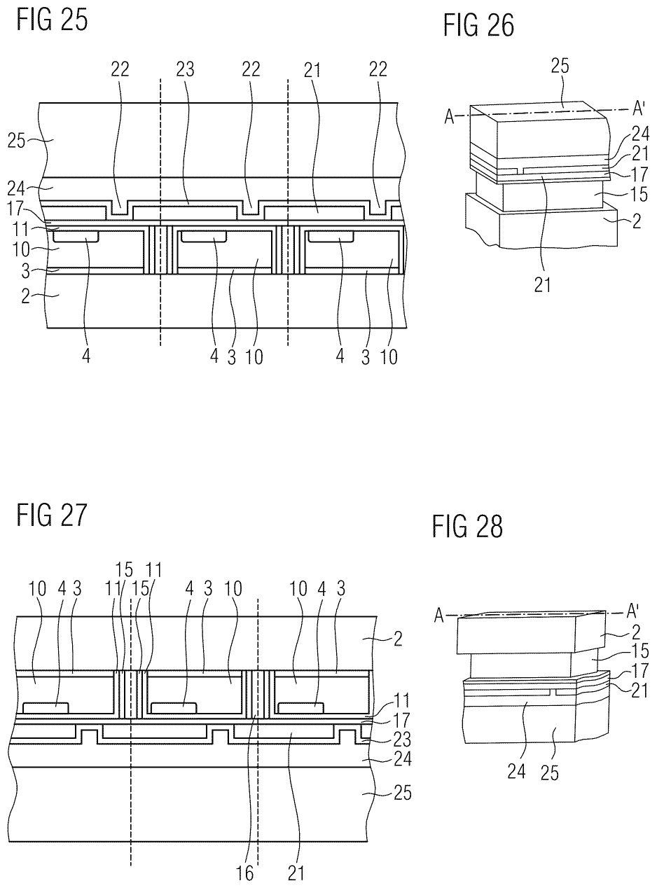

Then, a handling wafer 25 is connected to the polymer layer 24 (FIGS. 25 and 26).

Then, the wafer compound is flipped, as schematically shown in FIGS. 27 and 28.

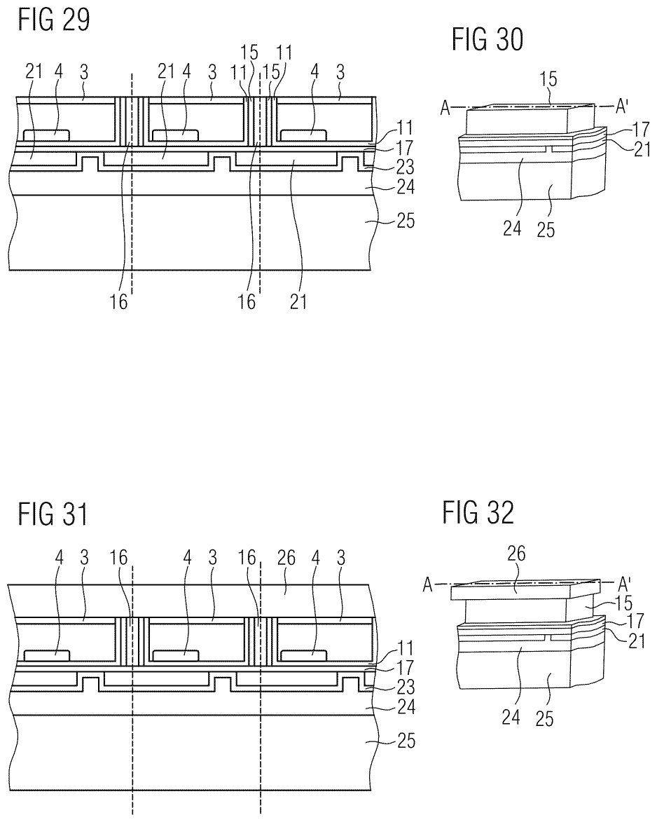

Then, the substrate 2 is removed, for example with grinding, polishing or etching. The oxide layer 3 forms an etch stop layer during etching of the substrate 2 (see FIGS. 29 and 30). After removal of the substrate 2, the epitaxial semiconductor layer stacks 10 are separated from each other by the gaps 16. The passivation layer 17 is freely accessible through the gaps 16.

The oxide layer 3 can be also removed in a separate step or can remain within the wafer compound. At present, the oxide layer 3 remains in the wafer compound.

After removal of the substrate 2, an optical filter layer 26 is applied over the first main surfaces 13 of the epitaxial semiconductor layer stacks 10. The optical filter layer 26 is applied on the oxide layer 3 and covers the oxide layer 3 at first completely (FIGS. 31 and 32). The optical filter layer 26 is at present in interference filter layer.

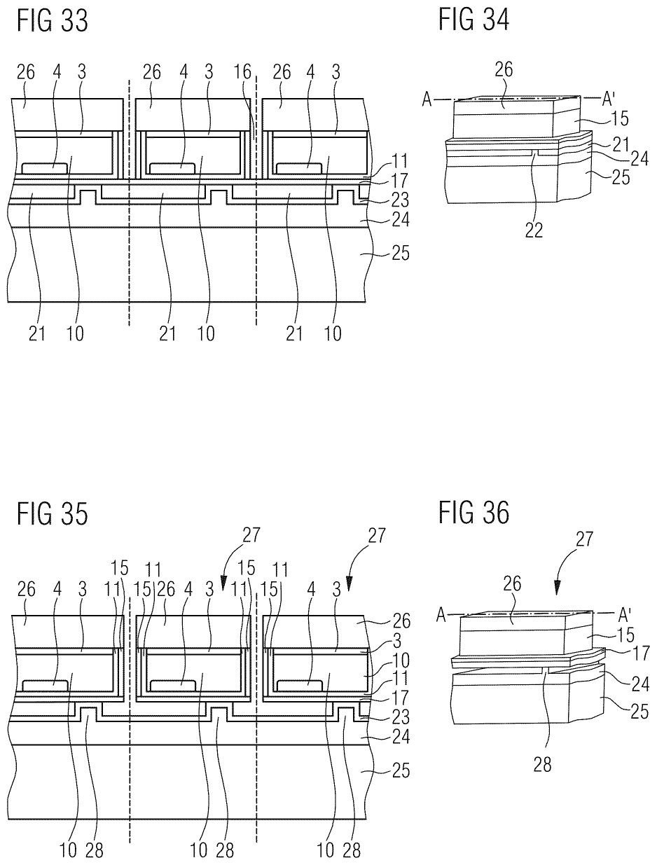

A further etching step, for example a mesa etching step, is performed such that the release layer 21 is exposed in the region of the trenches 9 (FIGS. 33 and 34).

Then, the release layer 21 is removed (FIGS. 35 and 36). A wafer compound is achieved wherein discrete electronic semiconductor chips 27 are connected to a handling wafer 25 only by bridging elements 28 formed from the polymer material within the recesses 22 in the release layer 21. The electronic semiconductor chips 27 can be transferred by a polymer stamp to other elements such as a connection carrier.

The electronic semiconductor chip 27 according to the exemplary embodiment of FIGS. 37 and 38 can be manufactured with the method of exemplary embodiment of FIGS. 1 to 36.

The electronic semiconductor chip 26 according to the exemplary embodiment of FIGS. 37 and 38 comprises an epitaxial semiconductor layer stack 10 with an electronic functional region 6. The electronic functional region 6 consists of a pn-junction 5 configured for detecting electromagnetic radiation of a first wavelength range during operation.

A first main surface 13 as well as side faces 12 of the epitaxial semiconductor layer stack 10 are completely covered with an electrically insulating layer 11, for example a silicon oxide layer. Over the side faces 12 of the epitaxial semiconductor layer stack 10 on the electrically insulating layer 11 an absorption layer 15 is deposited. The absorption layer 15 covers the side faces 12 of the epitaxial semiconductor layer stack 10 at present completely. The absorption layer 15 absorbs electromagnetic radiation of the first wavelength range to be detected by the pn-junction 5 during operation. For example, the absorption layer 15 consists of tungsten or highly doped polycrystalline silicon.

On a second main surface 29 of the epitaxial semiconductor layer stack 10 opposite to the first main surface 13 of the epitaxial semiconductor layer stack 10 an oxide layer 3, for example a silicon dioxide layer, is arranged.

A passivation layer 17 is applied over the first main surface 13 of the epitaxial semiconductor layer stack 10 on the electrically insulating layer 11. Openings 18 are arranged within the insulating layer 11 and the passivation layer 17, which are filled by tungsten plugs 19 and electrically conductively connected to further p-doped and n-doped regions 4, 7 within the epitaxial semiconductor layer stack 10. Further, the electronic semiconductor chip 27 according to the exemplary embodiment of FIGS. 37 and 38 comprises metallic contact layers 20 on the tungsten plugs 19. The tungsten plugs 19 and the metallic contact layers 20 form electrical mounting pads 30 at a back side surface 31 of the electronic semiconductor chip 27.

Further, the electronic semiconductor chip 27 comprises an optical filter layer 26. A surface of the optical filter layer 26 forms a radiation entrance surface 32 of the electronic semiconductor chip 26 configured for transmitting the electromagnetic radiation to be detected. The radiation entrance surface 32 is arranged at a front side surface 33 of the electronic semiconductor chip 27 opposite to the back side surface 31.

The electronic semiconductor chip of FIGS. 37 and 38 has small dimensions. Particularly, a thickness D of the electronic semiconductor chip does not exceed 20 microns, while an edge length EL of the electronic semiconductor chip is at most 100 microns.

The electronic semiconductor chip 27 according to the exemplary embodiment of FIG. 39 comprises, compared to the electronic semiconductor chip 27 according to the exemplary embodiment of FIGS. 37 and 38, an electronic functional region 6 consisting of an integrated circuit 34. The integrated circuit 34 is in particular configured to control a light emitting diode chip 35. A front side surface 33 of the electronic semiconductor chip 26 comprises an electrical mounting surface 36 configured for mounting the light emitting diode chip 35 to be controlled by the integrated circuit 34.

FIG. 40 shows schematically stage of a method according to a further exemplary embodiment. Particularly, the epitaxial semiconductor layer sequence 1 is compared to the method step shown in FIG. 1, directly applied to the substrate 2 without an oxide layer 3 in between. In that case, the substrate 2 is, for example, a highly doped silicon substrate 2, which can be removed by etching, for example dry or wet chemical etching. An etch stop after the removal of the substrate 2 is achieved during this method by the contrast formed by the high concentration of dopants within the substrate 2 compared to the low concentration of dopants in the epitaxial semiconductor layer sequence 1. For example, the dopant in the substrate 2 has a concentration of about 10¹⁴ cm⁻³ and the dopant in the epitaxial semiconductor layer sequence 2 has a concentration of about 10¹⁶ cm⁻³.

Starting from the method step as shown in FIG. 40, the electronic semiconductor chips 27 can be manufactured as already described in connection with FIGS. 3 to 36, omitting the oxide layer 3.

The display according to the exemplary embodiment of FIG. 41 comprises a connection carrier 36 such as a printed circuit board. A plurality of electronic semiconductor chips 27 is applied to the connection carrier 36, in particular electrically conductive and mechanically stable via electrically mounting pads 30 arranged at back side surfaces 31 of the electronic semiconductor chips 27.

Some electronic semiconductor chips 26 comprise an integrated circuit 34 as electronic functional region 6, as for example shown in FIG. 39. On a electrical mounting surface 36 of the electronic semiconductor chips comprising the integrated circuits 34, light emitting diode chips are mounted.

The electronic semiconductor chips 27 and, in particular, the integrated circuit 34 of the electronic semiconductor chips 27 are configured to control the light emitting diode chips 35 during operation of the display.

The electronic semiconductor chips 27 and the light emitting diode chips 35 have similar or equal dimensions such that they can be stacked above each other in an easy manner.

Further, the display according to the exemplary embodiment of FIG. 41 comprises an electronic semiconductor chip 27′ having a pn-junction 5 for photo detection as an electronic functional region 6. This electronic semiconductor chip 27′ is laterally arranged to the stacks of the electronic semiconductor chips 27 with the integrated circuit 34 and the light emitting diode chips 35 and is, for example, configured to measure ambient light.

The present application claims priority of the German application DE 102022131371.9, the disclosure content of which is inserted herein by reference.

The invention is not limited to the description of the embodiments. Rather, the invention comprises each new feature as well as each combination of features, particularly each combination of features of the claims, even if the feature or the combination of features itself is not explicitly given in the claims or embodiments.

### REFERENCES

1 epitaxial semiconductor layer sequence
2 substrate
3 oxide layer
4 n-doped region
5 pn-junction
6 electronic functional region
7 n-doped contact region
8 p-doped contact region
9 trench
10 epitaxial semiconductor layer stack
11 electrically insulating layer
12 side face of the epitaxial semiconductor layer stack
13 first main surface of the epitaxial semiconductor layer stack
14 bottom surface of the trench
15 absorption layer
16 gap
17 passivation layer
18 opening
19 tungsten plug
20 metallic contact layer
21 release layer
22 recess
23 adhesion layer
24 polymer layer
25 handling wafer
26 optical filter layer
27, 27′electronic semiconductor chips
28 bridging element
29 second main surface of the epitaxial semiconductor layer stack
30 Electrical Mounting Pad
31 back side surface
32 radiation entrance surface
33 front side surface of the electronic semiconductor chip
34 integrated circuit
35 light emitting diode chip
36 electrical mounting surface
37 connection carrier
38 further layer
GD growth direction
LD lateral direction
D thickness
EL edge length

1. A method for manufacturing a plurality of electronic semiconductor chips, comprising the steps:
providing an epitaxial semiconductor layer sequence with a plurality of electronic functional regions, the epitaxial semiconductor layer sequence being arranged on or over a substrate,
generating a plurality of trenches in the epitaxial semiconductor layer sequence, such that a plurality of epitaxial semiconductor layer stacks are created, wherein the trenches penetrate the epitaxial semiconductor layer sequence completely such that the substrate is freely accessible,
depositing absorption layers on or over side faces of the epitaxial semiconductor layer stacks in the trenches, the absorption layers being absorbent for electromagnetic radiation,
depositing a further layer on or over first main surfaces of the epitaxial semiconductor layer stacks, the further layer covering the trenches,
generating bridging elements connecting the epitaxial semiconductor layer stacks starting from the first main surfaces to a handling wafer, and
removing the substrate at least partially.

2. The method according to claim 1, wherein
the electronic functional regions comprise pn-junctions configured for detecting electromagnetic radiation of a first wavelength range during operation, and
the absorption layers absorb electromagnetic radiation of the first wavelength range.

3. The method according to claim 2, wherein
the absorption layers are electrically conductive, and
electrically insulating layers are deposited between the epitaxial semiconductor layer stacks and the absorption layers.

4. The method according to claim 1, wherein
the further layer is a passivation layer and/or a release layer.

5. The method according to claim 1, wherein the step of generating the bridging elements comprises:
depositing the release layer on or over the first main surfaces of the epitaxial semiconductor layer stacks, , the release layer covering the trenches,
generating recesses in the release layer, the recesses completely penetrating the release layer,
depositing a polymer layer on or over the release layer, a material of the polymer layer filling the recesses in the release layer, and
removing the release layer such that the epitaxial semiconductor layer stacks are connected to the handling wafer by the bridging elements formed from the material of the polymer layer in the recesses of the release layer.

6. The method according to claim 5, wherein an adhesion layer is deposited between the polymer layer and the release layer, the adhesion layer having enhanced adhesion to the polymer layer and to the release layer compared to the adhesion between the polymer layer and the release layer.

7. The method according to claim 5, wherein the handling wafer is deposited on or over the polymer layer before removing the substrate.

8. The method according to claim 1, further comprising the step:
depositing an optical filter layer on or over second main surfaces of the epitaxial semiconductor layer stacks, the optical filter layer covering the trenches.

9. The method according to claim 8, wherein
the electronic functional regions comprise pn-junctions configured for detecting electromagnetic radiation of a first wavelength range during operation, and
the optical filter layer is an interference filter layer filtering a part of the electromagnetic radiation of the first wavelength range.

10. An electronic semiconductor chip 27, comprising:
an epitaxial semiconductor layer stack with an electronic functional region comprising a pn-junction configured for detecting electromagnetic radiation of a first wavelength range during operation,
an absorption layer covering side faces of the epitaxial semiconductor layer stack, the absorption layer absorbs electromagnetic radiation of the first wavelength range, wherein the absorption layer forms a side surface of the electronic semiconductor chip at least partially,
at least two electrical mounting pads configured for electrically conductive and mechanically stable connection of the electronic semiconductor chip, the electrical mounting pads being arranged at a back side surface of the electronic semiconductor chip,
a radiation entrance surface configured for transmitting the electromagnetic radiation to be detected, the radiation entrance surface being arranged at a front side surface of the electronic semiconductor chip opposite to the back side surface, and
wherein the absorption layer comprises a metallic material or a highly doped polycrystalline silicon.

11. An electronic semiconductor chip comprising:
an epitaxial semiconductor layer stack with an electronic functional region comprising an integrated circuit configured for controlling a light emitting diode chip,
an absorption layer covering side face of the epitaxial semiconductor layer stack,
at least two electrical mounting pads configured for electrically conductive and mechanically stable connection of the electronic semiconductor chip, the electrical mounting pads being arranged at a back side surface of the electronic semiconductor chip,
an electrical mounting surface configured for mounting the light emitting diode chip to be controlled, the electrical mounting surface being arranged at a front side surface of the electronic semiconductor chip opposite to the back side surface, and
wherein the absorption layer comprises a metallic material or a highly doped polycrystalline silicon.

12. The electronic semiconductor chip according to claim 11, wherein a thickness of the electronic semiconductor chip does not exceed 20 micrometer.

13. The electronic semiconductor chip according to claim 11, wherein an edge length of the electronic semiconductor chip does not exceed 100 micrometer.

14. A display comprising:
an electronic semiconductor chip according to claim 10,
a light emitting diode chip emitting electromagnetic radiation of a second wavelength range during operation.

15. A display comprising:
an electronic semiconductor chip according to claim 11,
a light emitting diode chip emitting electromagnetic radiation of a second wavelength range, wherein
the electronic semiconductor chip controls the light emitting diode chip during operation.

16. The display according to claim 15, wherein the electronic semiconductor chip and the light emitting diode chip are stacked above each other.

17. The electronic semiconductor chip according to claim 10, wherein a thickness of the electronic semiconductor chip does not exceed 20 micrometer.

18. The electronic semiconductor chip according to claim 10, wherein an edge length of the electronic semiconductor chip does not exceed 100 micrometer.

19. A display comprising:
an electronic semiconductor chip according claim 11,
a light emitting diode chip emitting electromagnetic radiation of a second wavelength range during operation.
